(19) United States
(12) Patent Application Publication
(10) Pub. No.: US 2010/0035051 A1
(43) Pub. Date: Feb. 11, 2010

(54) Wear-resistant ceramic coating

(76) Inventors: Bekir Sami Yilbas, Dhahran (SA); Muhammad A. Hawwa, Dhahran (SA)

Correspondence Address: LITMAN LAW OFFICES, LTD., POST OFFICE BOX 15035, CRYSTAL CITY STATION, ARLINGTON, VA, 22215-0035, US

(21) Appl. No.: 12/222,446

(22) Filed: Aug. 8, 2008

(51) Int. Cl. B32B 15/04; B32B 18/00; B05D 3/06; C23C 14/34

(52) U.S. Cl. 428/336; 428/472.1; 428/334; 427/554; 204/192.1

(57) ABSTRACT

The wear-resistant ceramic coating is a coating formed with a first thin film nitride layer formed by laser nitriding and a second thin film layer of titanium nitride or other ceramic material formed by physical vapor deposition. For example, the coating may be formed on a Ti-6Al-4V alloy by first directing a CO₂ laser beam towards the surface of the alloy while subjecting the surface to a flow of pressurized pure nitrogen. This process results in the formation of a first nitride layer approximately 80 microns in thickness by laser melting. The first layer is polished to a smooth surface. Then a thin film (about two micrometers) of titanium nitride is applied over the first layer by physical vapor deposition, e.g., by sputtering at 260° C. Similar coatings may be applied to other titanium alloys, such as Ti-5Al-2.5Fe, or to other metals, such as high-speed steel (HSS).

### BACKGROUND OF THE INVENTION

1. Field of the Invention

The present invention relates to coatings, and more particularly to a wear-resistant ceramic coating and method of applying the coating, which is especially useful for prosthetic devices, such as hip prostheses, that are made of titanium or titanium alloys.

2. Description of the Related Art

Titanium alloys are metallic materials that contain a mixture of titanium and other chemical elements. Such alloys have very high tensile strength and toughness, light weight, extraordinary corrosion resistance, and the ability to withstand extreme temperatures. Titanium and titanium alloys are used in airplanes, missiles and rockets where strength, low weight and resistance to high temperatures are important. Since titanium does not react within the human body, it is used to create artificial hips, pins for setting bones and for other biological implants.

Although commercially pure titanium has acceptable mechanical properties and has been used for orthopedic and dental implants, for most application titanium is alloyed with small amounts of aluminum and vanadium, typically six percent and four percent respectively, by weight. This mixture has a solid solubility that varies dramatically with temperature, allowing it to undergo precipitation strengthening. This heat treatment process is carried out after the alloy has been worked into its final shape but before it is put to use, allowing much easier fabrication of a high-strength product.

Some alloying elements raise the alpha to beta transition temperature, i.e., alpha stabilizers, while others lower the transition temperature, i.e., beta stabilizers. Aluminum, gallium, germanium, carbon, oxygen and nitrogen are alpha stabilizers. Molybdenum, vanadium, tantalum, niobium, manganese, iron, chromium, cobalt, nickel, copper and silicon are beta stabilizers. Titanium alloys are usually classified as alpha alloys, near alpha alloys, alpha plus beta alloy or beta alloys, depending on the type and amount of alloying elements. Generally, alpha phase titanium is more ductile and beta phase titanium is stronger, but more brittle. Alpha beta titanium has mechanical properties that are in between both.

While there are a number of titanium alloy standards that are graded and numbered for reference, the most commonly used titanium alloy contains six percent aluminum and four percent vanadium. It is also known as Ti-6Al-4V or R56400. This alpha beta alloy is the workhorse alloy of the titanium industry. Since it is the most commonly used alloy (over seventy percent of all alloy grades melted are a subgrade of Ti-6Al-4V), its uses span many aerospace, airframe and engine component, oil and gas extraction, surgery and medicine where successful application demands high levels of reliable performance.

High levels of reliable performance are critical in applications where equipment, once installed, cannot be readily maintained or replaced. There is no more challenging use in this respect than implants in the human body. Here, the effectiveness and reliability of implants, and medical and surgical instruments and devices is an essential factor in saving lives and in the long term relief of suffering and pain. Implantation represents a potential assault on the chemical, physiological and mechanical structure of the human body.

There is nothing comparable to a metallic implant in living tissue. Most metals in body fluids and tissue are found in stable organic complexes. Corrosion of implanted metal by body fluids, results in the release of unwanted metallic ions, with likely interference in the processes of life. Corrosion resistance is not sufficient of itself to suppress the body's reaction to cell toxic metals or allergenic elements, such as nickel, and even in very small concentrations from a minimum level of corrosion, these may initiate rejection reactions. Titanium is judged to be completely inert and immune to corrosion by all body fluids and tissue, and is thus wholly biocompatible.

However, titanium is still a soft metal, and for use in prostheses, is often in porous form. Thus, even though titanium alloys are well known for their superior mechanical properties and total biocompatibility, the alloys have been shown in some situations to have low resistance to abrasion. This property has been shown by detecting fine particles of titanium in tissues and organs associated with titanium implants.

The variety of techniques developed to harden the surface of titanium implants that impinges upon or form joints with bone or in the human body attests to the continuing need for improving the wear resistance of titanium, titanium alloys, and similar soft metals. Thus, a wear-resistant ceramic coating solving the aforementioned problems is desired.

### SUMMARY OF THE INVENTION

The wear-resistant ceramic coating is a coating formed with a first thin film nitride layer formed by laser nitriding and a second thin film layer of titanium nitride or other ceramic material formed by physical vapor deposition. For example, the coating may be formed on a Ti-6Al-4V alloy by first directing a CO₂ laser beam towards the surface of the alloy while subjecting the surface to a flow of pressurized pure nitrogen. This process results in the formation of a first nitride layer approximately 80 microns in thickness by laser melting. The first layer is polished to a smooth surface. Then a thin film (about two micrometers) of titanium nitride is applied over the first layer by physical vapor deposition, e.g., by sputtering at 260° C. Similar coatings may be applied to other titanium alloys, such as Ti-5Al-2.5Fe, or to other metals, such as high-speed steel (HSS).

The multiple thin film layers are thought to reduce strain discontinuity that otherwise results when moving from a hard outer surface directly to a softer subsurface, since the wear-resistant ceramic coating interposes an intermediate layer between the hard ceramic outer layer and the soft or porous surface of the substrate, the intermediate layer having a composition and hardness more similar to the surface structure of the ceramic outer layer than the surface of the substrate. The intermediate ceramic thin film layer provides a lower degree of discontinuity that reduces the surface strain and greatly lowers the susceptibility of the material to surface stress fractures and wear from abrasion.

These and other features of the present invention will become readily apparent upon further review of the following specification and drawings.

### BRIEF DESCRIPTION OF THE DRAWINGS

FIG. 1 is a diagrammatic representation of the differential layers of hardness resulting from an experiment with a partially boiled egg, showing the principles underlying a wear-resistant ceramic coating according to the present invention.

FIGS. 2A and 2B is are graphic representations of the strain distribution in bi-laminate materials, further showing the principles underlying a wear-resistant ceramic coating according to the present invention.

FIG. 3 is a diagrammatic representation of a laser nitriding step for forming a wear-resistant ceramic coating according to the present invention.

FIG. 4 is a diagrammatic representation of the hardness zones produced after the laser nitriding step of forming a wear-resistant ceramic coating according to the present invention.

FIG. 5 is a diagrammatic representation of a physical vapor deposition step for forming a wear-resistant ceramic coating according to the present invention.

Similar reference characters denote corresponding features consistently throughout the attached drawings.

### DETAILED DESCRIPTION OF THE PREFERRED EMBODIMENTS

The present invention relates to a wear-resistant ceramic coating formed with a first thin film nitride layer formed by laser nitriding and a second thin film layer of titanium nitride or other ceramic material formed by physical vapor deposition. The following considerations generally illustrate the principles underlying the formation of a wear-resistant ceramic coating according to the present invention.

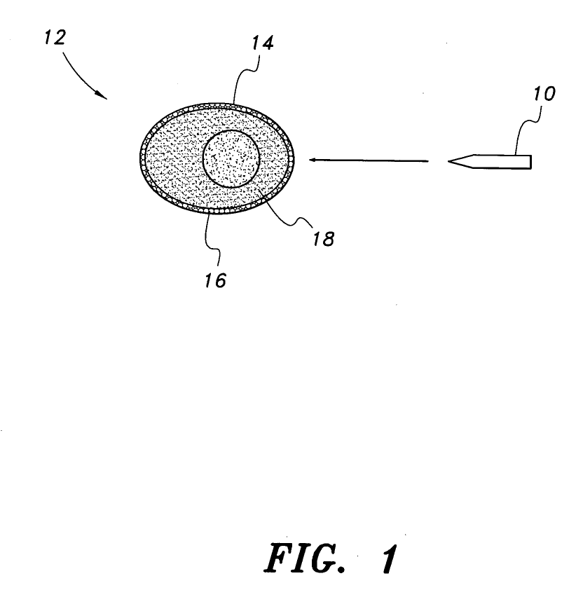

FIG. 1 diagrammatically illustrates an experiment performed on an egg to develop the method of enhancing the wear resistance of ceramics. In the experiment illustrated by FIG. 1, a pin 10 was introduced to a partially boiled egg 12. In contrast to the catastrophic failure of an eggshell when a pin 10 is introduced to a raw egg, in this experiment the boiling of the egg 12 resulted in the formation of three zones of decreasing hardness, the shell 14, the partially cooked dense zone 16 beneath the shell 14, and the soft portion 18 nearer the center of the egg 12. When the pin 10 was introduced to the shell 14 of the partially cooked egg 12, the shell 14 is cracked, but no catastrophic failure takes place.

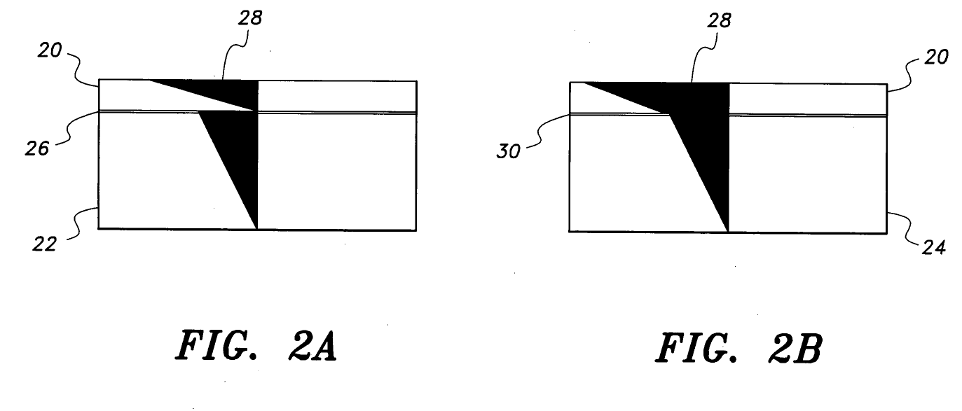

FIGS. 2A and 2B are a diagrammatic representations of strain distribution in bi-laminate materials. In FIG. 2A, a hard material 20 is shown overlaying a much softer material 22. The strain at the interface 26 of the two materials is illustrated by the shaded portion 28. In FIG. 2B, the hard material 20 is shown overlaying a slightly softer material 24. The reduction of the strain at the interface 30 is shown by the shaded portion 28.

The conclusion drawn by the inventors from these observations is that in order to enhance the abrasive wear resistance of a surface, it is necessary not only to harden the surface, but also to coat it with a thin film. While there is severe strain discontinuity when moving directly from a hard surface layer to a soft inner substrate, having two hard “outer” layers produces only a “moderate” strain discontinuity at the interface. The lower degree of strain discontinuity makes the material less susceptible to fracture.

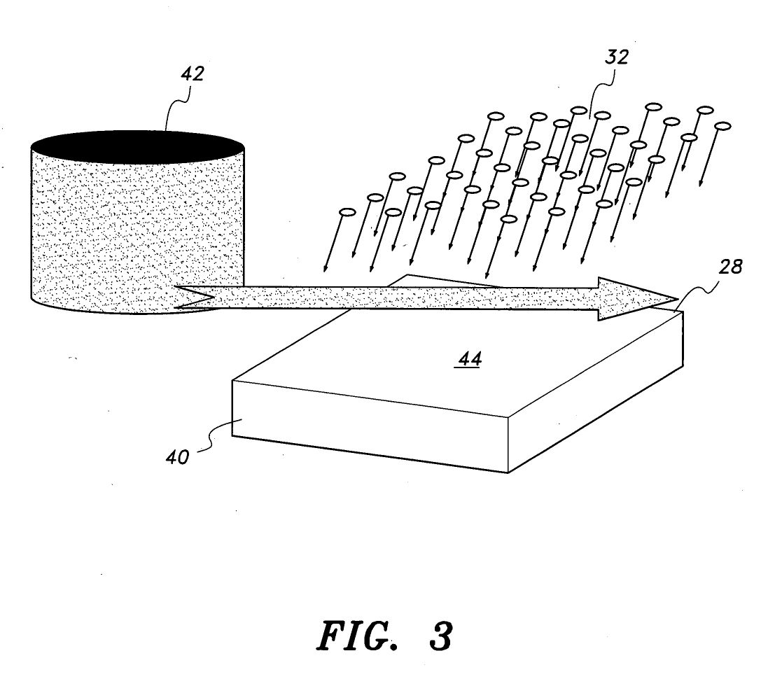

FIG. 3 is a diagrammatic representation of the first step for forming a wear-resistant ceramic coating according to the present invention. In FIG. 3, a carbon dioxide (CO₂) laser beam 32 is directed towards the surface 44 of a metal alloy 40, e.g., Ti-6Al-4V, while a stream of pressurized pure nitrogen 42 is allowed to flow over the alloy 40.

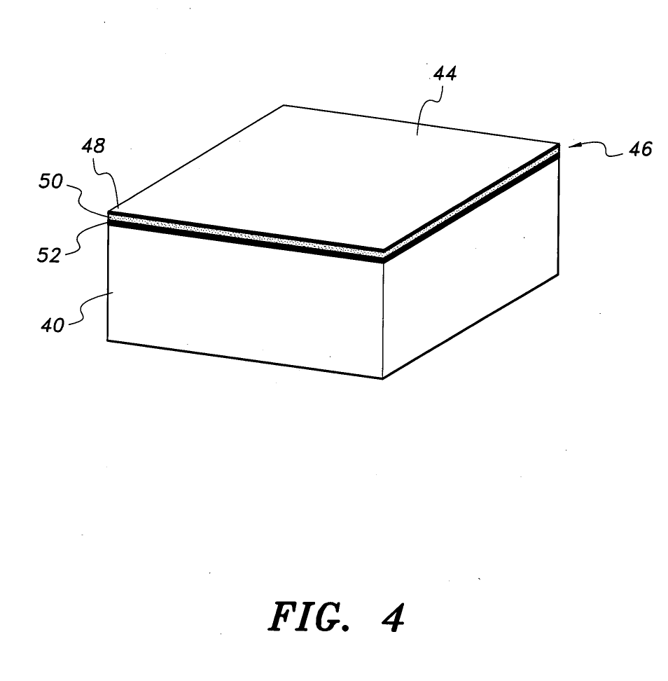

FIG. 4 is a diagrammatic representation showing the resulting nitride layer 46 formed on the surface 44 of the alloy 40. The nitride layer 46 is up to 80 microns thick. A hard Delta zone 48 is formed on the surface 44 of the titanium alloy sample 40. Underneath, the nitride layer 46 is a less hard Epsilon zone 50. A much softer Perspiration Zone 52 is formed farthest from the surface 44. This process causes roughening of the surface 44 that requires polishing. The formation of the nitride layer 46 is not dependant on high temperature treatment, but is caused by laser melting of the surface of the alloy in the presence of nitrogen.

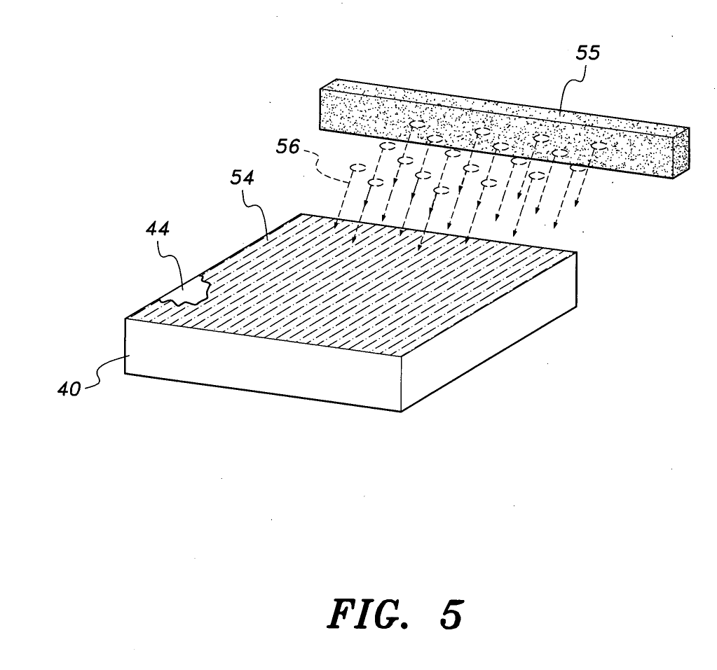

FIG. 5 diagrammatically illustrates the final step of the method. A thin film 54 is applied by a physical vapor deposition process, such as sputtering TiN 56 at a temperature of 260° C. onto the surface 44 of the alloy 40. The thin film layer 54 deposed by physical vapor deposition may be about two micrometers (2 μm) in thickness. The gradual transition in hardness from the outer ceramic layer to the surface of the substrate reduces strain discontinuity, thereby lessening the risk of fracture and producing a greater degree of resistance to wear from abrasion. In FIG. 5, container 55 is shown diagrammatically and represents an exemplary container or other source for the sputtering material 56.

As used herein, the term “physical vapor deposition” refers to any of a variety of processes used to deposit a thin layer of a vaporized material onto a substrate under vacuum by physical processes, as opposed to chemical processes. The term encompasses evaporative deposition, electron beam deposition, sputter deposition, arc deposition, and pulsed laser deposition, among others. Sputter deposition refers to a process of bombarding a target material with ions to dislodge atoms from the target material, which condense and form a thin layer on the substrate.

It is to be understood that the coating must be prepared in two reactors or sequential steps because of the different process parameters. Although particularly useful for providing a ceramic coating for a Ti-6Al-4V alloy, it is believed that the same process may provide a wear-resistant ceramic coating for other titanium alloys, such as Ti-5Al-2.5Fe, or for alloys of other metals, such as high-speed steel (HSS).

It is to be understood that the present invention is not limited to the embodiments described above, but encompasses any and all embodiments within the scope of the following claims.

We claim:

1. A ceramic coating for a metal alloy substrate, comprising:
a first thin film laser nitride layer formed on the substrate; and
a second thin film layer deposited on the laser nitride layer by physical vapor deposition.

2. The ceramic coating according to claim 1, wherein said second thin film layer comprises a metallic layer.

3. The ceramic coating according to claim 1, wherein said second thin film layer comprises a second nitride layer.

4. The ceramic coating according to claim 1, wherein said second thin film layer comprises a layer of titanium nitride.

5. The ceramic coating according to claim 1, wherein said first layer has a thickness of about 80 microns.

6. The ceramic coating according to claim 1, wherein said second layer has a thickness of about two micrometers (2 μm).

7. The ceramic coating according to claim 1, wherein said first thin film nitride layer comprises a laser melted thin film.

8. The ceramic coating according to claim 1, wherein said second thin film layer comprises a sputtered layer of titanium nitride.

9. A method for forming a wear-resistant ceramic coating on a substrate, comprising the steps of:
directing a laser beam towards the substrate while flowing pressurized nitrogen across the substrate in order to form a first thin film nitride layer on the substrate by laser melting;
polishing the laser-nitrided substrate to form a polished surface; and
applying a second thin film layer onto the polished surface by physical vapor deposition.

10. The method for forming a wear-resistant ceramic coating according to claim 9, wherein the step of applying the second thin film layer comprises sputtering titanium nitride at a temperature of 260° C. onto the polished surface.

11. The method for forming a wear-resistant ceramic coating according to claim 9, wherein the first thin film layer is about 80 microns thick.

12. The method for forming a wear-resistant ceramic coating according to claim 9, wherein the second thin film layer is about two micrometers (2 μm) thick.

13. A metal alloy having a wear-resistant ceramic coating, comprising:
a metal alloy substrate;
a laser-melted thin film nitride layer coating the substrate; and
a thin film metallic layer deposited by physical vapor deposition s overlying the laser-melted thin film nitride layer.

14. The metal alloy according to claim 13, wherein said metal alloy comprises Ti-6Al-4V.

15. The metal alloy according to claim 14, wherein said thin film metallic layer deposited by physical vapor deposition comprises a sputtered layer of titanium nitride.

16. The metal alloy according to claim 13, wherein said laser-melted thin film nitride layer is about 80 microns thick.

17. The metal alloy according to claim 13, wherein said thin film metallic layer deposited by physical vapor deposition is about two micrometers (2 μm) thick.
